(19) United States
(12) Patent Application Publication
(10) Pub. No.: US 2005/0277230 A1
(43) Pub. Date: Dec. 15, 2005

(54) Process for producing a chip arrangement provided with a molding compound

(76) Inventors: Axel Brintzinger, Dresden (DE); Octavio Trovarelli, Dresden (DE)

Correspondence Address: SLATER & MATSIL LLP, 17950 PRESTON ROAD, SUITE 1000, DALLAS, TX, 75252, US

(21) Appl. No.: 11/137,109

(22) Filed: May 25, 2005

(30) Foreign Application Priority Data
May 25, 2004 (DE) 10 2004 026 092.3

(51) Int. Cl. H01L 21/44; H01L 21/48; H01L 21/50

(52) U.S. Cl. 438/125

(57) ABSTRACT

A semiconductor device includes a semiconductor chip with a plurality of bonding pads at an upper surface and a passivation layer overlying the upper surface. A rewiring layer electrically coupling ones of the bonding pads to corresponding ones of a plurality of contact pads. The rewiring layer is formed by forming a first conductor and forming a covering layer of a precious metal over the first conductor. After forming the rewiring layer, a portion of the precious metal is removed from over the first conductor between the contact pads and bonding pads.

This application claims priority to German Patent Application 10 2004 026 092.3, which was filed May 25, 2004, and is incorporated herein by reference.

### TECHNICAL FIELD

The invention relates to a chip arrangement and a process for producing a chip arrangement.

### BACKGROUND

In SGRAM products, the chips are equipped with a peripheral arrangement of bonding pads, i.e., the bonding pads are arranged along the outer edges of the chip. In this case, the chips are surrounded by a housing, produced, for example, by molding, with the chips being chip-bonded to a substrate in the traditional face-up technology, i.e., with the active side facing upward. For electrical contact-connection, wire bridges connect the bonding pads on the chip to the contact islands on the substrate on the chip side.

Furthermore, on the opposite side from the chip, the substrate is provided with soldering balls (microballs, μ-balls), which are connected to the contact islands via rewiring in the substrate. To enable this to be realized, multi-layer substrates are used. Housing arrangements of this type are also referred to, inter alia, as an FBGA (fine ball grid array).

Recently, a technology has been developed that makes it possible by simple means to apply a redistribution layer to a completed chip, which is still joined to the wafer, i.e., to its passivation layer, which is the layer that protects the chip from harmful environmental influences.

This redistribution layer can be used to rewire the bonding pads that are kept clear in the passivation layer to other more favorable positions by means of a metallic interconnect. This means that bonding pads can be, as it were, “laid” independently of the interconnect structure in the chip by way of the redistribution layer.

This redistribution layer (RDL) usually has a fixedly predetermined layer structure by virtue of first of all a seed layer being applied to the uppermost passivation layer on the chip, then a layer sequence of copper, nickel and gold being applied to the seed layer in accordance with the desired interconnect structure of the redistribution layer by means of standard photolithographic processes and layer deposition.

The nickel layer, which is located on the copper (which has been deposited for example by electroplating), serves to protect the copper layer from corrosion. The gold layer, which is deposited on the nickel, is required in order to allow contact-connection of the reroute layer contact surfaces, for example by soldering or wire-bonding.

It is generally known that the bonding between a gold layer as the uppermost layer of a structure and a molding compound is extremely inadequate. This is because of the particular surface structure of gold, i.e., the surface of gold is particularly smooth, so that the bonding of a molding compound to a gold layer is not very good. This effect also occurs in a similar way with other precious-metal coatings, e.g., comprising Ag, Pt, etc.

The inevitable poor bonding of the molding compound to gold is not a problem if the proportion of the surface area of the chip formed by gold layers is small. However, as soon as larger proportions of the surface area of a chip have redistribution layers of this type, poor bonding of the molding compound ensues.

This poor bonding may cause the molding compound to become partially or completely detached even during simple handling of a chip arrangement of this type, or at the latest in the event of a fluctuating temperature load, with the associated thermal stresses. In both cases, the chip arrangement would become unusable.

A large and therefore disruptive proportion of the surface of the redistribution layer is found, for example, on chips that have a single-row or multi-row central arrangement of bonding pads, which are then rewired to the edge of the chips by means of the reroute layer.

It is in principle possible for the redistribution layer to be coated with a dielectric layer in order to create favorable bonding conditions for the molding compound. However, this requires an additional process and lithography step. However, an operation of this type is not desirable since the additional dielectric has to be dried, and consequently the processing of a dielectric entails an additional thermal budget for the wafer and has an adverse effect on the chip data, e.g. the moisture properties.

Another possible way of improving the bonding between the gold layer and the molding compound consists in subjecting the gold layer to a plasma treatment prior to the molding operation. However, this is a technically highly complex and expensive process.

### SUMMARY OF THE INVENTION

In one aspect, the invention provides a process for producing a chip arrangement provided with a molding compound, in which the drawbacks described are avoided and in which, in particular, good bonding between the active side of the chip and a molding compound surrounding is ensured.

In one embodiment, the invention is based on a process of the type described in the introduction by virtue of the fact that after patterning of the rewiring, a resist is deposited on the chip and exposed in such a manner that after the resist has been developed, the upper precious-metal layer is uncovered between the bonding pads and that the uncovered precious-metal layer is then removed by etching.

In a refinement of the invention, the precious metal used is preferably gold.

To prevent environmental influences from affecting the uncovered rewiring after the etching of the gold layer, the chip arrangement is surrounded by a molding compound immediately after the etching of the gold layer.

### DESCRIPTION OF THE DRAWINGS

The invention is to be explained in more detail below on the basis of an exemplary embodiment. In the associated figures of the drawings:

FIG. 1 (prior art) shows a cross section through a rewiring (redistribution layer), which has been built up on a first passivation on the active side of a chip;

FIG. 2 (prior art) shows a plan view of the active side of a chip in accordance with FIG. 1, with a rewiring distributed over its surface, so as to electrically connect the contact pads on the chip to contact bumps;

FIG. 3 (prior art) diagrammatically depicts the rewiring on the active side of a chip, which electrically connects the (old) bonding pads of the chip to “new” bonding pads on the chip, with the top layer of the rewiring and the bonding pads being a layer of gold;

FIG. 4 diagrammatically depicts the rewiring after the deposition of resist, the exposure of the regions in which Au is not required, and the developing of the resist;

FIG. 5 shows the rewiring in accordance with FIG. 4 after the Au etch; and

FIG. 6 shows the completed rewiring, in which only the bonding pads are still provided with an Au coating, while the remaining regions have Ni as their top layer.

The following list of reference symbols can be used in conjunction with the figures:
1 Chip
2 Passivation
3 Rewiring
4 Bonding pad
5 Contact pad
6 Contact bump
7 Interconnect
8 Cu layer
9 Ni layer
10 Au layer

### DETAILED DESCRIPTION OF ILLUSTRATIVE EMBODIMENTS

In the preferred embodiment, the invention relates to a process for producing a chip arrangement provided with a molding compound and having a chip that is chip-bonded face-up on a substrate and has a preferably central arrangement of bonding pads, a rewiring composed of copper, nickel and a covering layer of a precious metal, which rewires the bonding pads on the chip having been deposited on the chip above a passivation layer, and the substrate being ultimately surrounded by a molding compound on the active side of the chip. Other modifications are also possible.

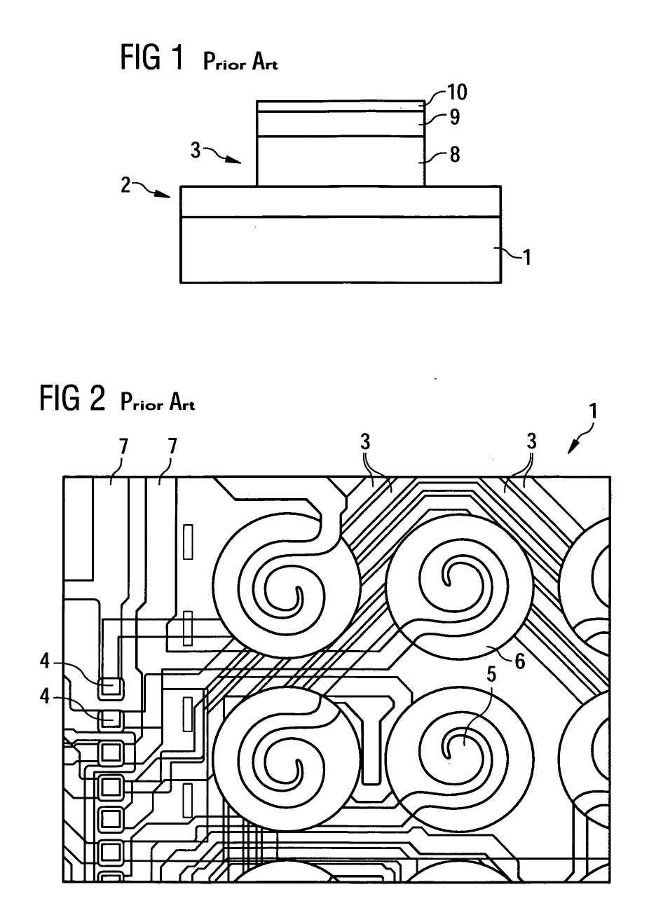

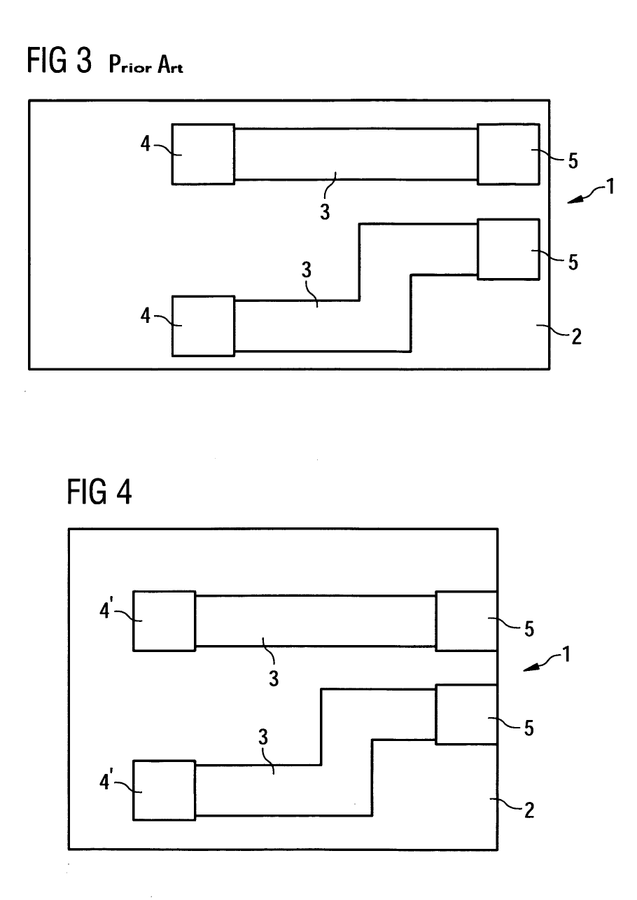

FIGS. 1 to 3 show a rewiring 3 that has been built up on the active side of a chip 1 above a passivation 2 in accordance with the prior art. This rewiring 3 connects the bonding pads 4 on the chip 1 to contact pads 5 on contact bumps 6 (FIG. 2). FIG. 2 also shows the interconnects 7 of the top metallization level of the chip 1, which connect the bonding pads 4 to active elements of the chip 1.

The layer structure of the rewiring 3 can be seen from FIG. 1 and comprises a Cu layer 8 on the passivation 2, an Ni layer 9 covering the Cu layer 8, and an upper Au layer 10. This redistribution layer (RDL) or rewiring layer can be formed by applying a seed layer to the uppermost passivation layer on the chip. Then a layer sequence of copper, nickel and gold is applied to the seed layer in accordance with the desired interconnect structure of the rewiring layer by means of standard photolithographic processes and layer deposition. In one embodiment, the copper is electrodeposited (masklessly) onto the seed layer. In other embodiments, other materials (e.g., tungsten, aluminum, titanium and their compounds or alloys) can be used as the rewiring layer.

FIG. 4 now diagrammatically depicts the rewiring 3 after the deposition of resist, the exposure of the regions of the rewiring 3 between the bonding and contact pads 4, 5, in which Au is not required, and the developing of the resist. The contact and bonding pads 4, 5 are here covered with a resist 4′, 5′. This is followed by an Au etch, in which the Au layer 10 on the rewiring 3 is removed between the contact and bonding pads 4, 5 so as to uncover the Ni layer 9. (FIG. 5)

FIG. 5 shows the completed rewiring 3, in which only the bonding and contact pads 4, 5 are still provided with an Au coating, while the remaining regions have Ni as their top layer. This structure can then be molded, and very good bonding of the molding compound to the chip 1 is achieved on account of the small proportion of the surface formed by Au.

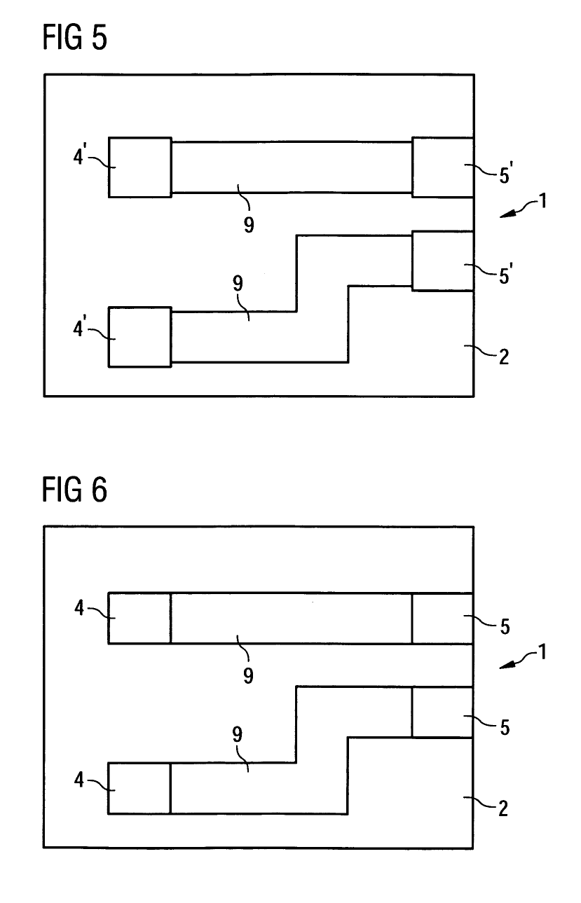

FIG. 6 shows the completed rewiring, after the resist 4′, 5′ has been removed, in which only the bonding pads are still provided with an Au coating, while the remaining regions have Ni as their top layer. In another embodiment, the Au coating is also removed from the bond pads 4 so that Ni is the top layer of these regions.

1. A method of making a semiconductor device, the method comprising:
providing a semiconductor chip that includes a plurality of bonding pads at an upper surface and a passivation layer overlying the upper surface;
forming a rewiring layer over the passivation, the rewiring layer electrically coupling ones of the bonding pads to corresponding ones of a plurality of contact pads, wherein forming a rewiring layer comprises forming a first conductor and forming a covering layer of a precious metal over the first conductor;
after forming the rewiring layer, removing a portion of the precious metal from over the first conductor between the contact pads and bonding pads.

2. The method of claim 1, wherein removing a portion of the precious metal comprises:
forming a resist over the semiconductor chip;
patterning the resist such that the precious metal is uncovered between the bonding pads and contact pads; and
removing uncovered portions of the precious metal layer.

3. The method of claim 1, further comprising forming a molding compound on an active side of the chip over the rewiring layer.

4. The method of claim 1, wherein forming a first conductor comprises forming a copper layer.

5. The method of claim 4, further comprising forming nickel over the copper.

6. The method of claim 5, wherein the precious metal comprises gold.

7. The method of claim 1, wherein the precious metal comprises gold.

8. The method of claim 7, further comprising surrounding the semiconductor chip, including the rewiring layer, with a molding compound immediately after removing the portion of the precious metal.

9. The method of claim 1, wherein the precious metal comprises silver.

10. The method of claim 1, wherein the precious metal comprises platinum.

11. The method of claim 1, wherein forming a rewiring layer comprises:
forming a seed layer;
patterning and etching the seed layer; and
selectively forming the first conductor over the seed layer.

12. The method of claim 8, wherein the seed layer and the first conductive layer comprises copper.

13. A process for producing a chip arrangement having a chip that is chip-bonded face-up on a substrate and has a preferably central arrangement of bonding pads, a rewiring composed of copper, nickel and a covering layer of a precious metal, which rewires the bonding pads on the chip, having been deposited on the chip via a passivation layer, the process comprising:
after forming the rewiring, depositing a resist on the chip;
exposing the resist in such a manner that after the resist has been developed, the precious metal layer is uncovered between the bonding and contact pads; and
removing the uncovered precious metal layer by etching.

14. The process of claim 13, wherein the precious metal used is gold.

15. The process of claim 14, wherein the chip arrangement is surrounded by a molding compound immediately after the etching of the Au layer.

16. The process of claim 13, further comprising surrounding the chip and the substrate with a molding compound on an active side of the chip.

17. A semiconductor device comprising:
a semiconductor chip that includes integrated circuitry and an uppermost level of metal, the uppermost level of metal including bonding pads;
a passivation layer overlying the uppermost level of metal;
a plurality of contact pads overlying the passivation layer;
a rewiring layer overlying the passivation and electrically coupling ones of the bonding pads to corresponding ones of the contact pads; and
regions of a precious metal overlying the contact pads but not overlying portions of the rewiring layer between the bonding pads and the contact pads.

18. The device of claim 17, wherein the regions of precious metal overlie the contact pads and the bonding pads.

19. The device of claim 17, wherein the rewiring layer comprises a copper layer and a nickel layer overlying the copper layer and wherein the contact pads comprise a copper region, a nickel region overlying the copper region and a gold region overlying the nickel region.

20. The device of claim 17, wherein the precious metal comprises gold.
